(19) United States
(12) Patent Application Publication
(10) Pub. No.: US 2016/0351573 A1
(43) Pub. Date: Dec. 1, 2016

(54) SEMICONDUCTOR DEVICE AND METHOD FOR MANUFACTURING THE SAME

(71) Applicants: Hiroshi YOSHINO, Tokyo (JP); Gou KAWAGUCHI, Tokyo (JP)

(72) Inventors: Hiroshi Yoshino, Tokyo (JP); Gou Kawaguchi, Tokyo (JP)

(21) Appl. No.: 14/777,600

(22) PCT Filed: Mar. 20, 2014
(86) PCT No.: PCT/JP2014/057667

§ 371 Date: Sep. 16, 2015

(30) Foreign Application Priority Data
Mar. 25, 2013 (JP) 2013-061501

(51) Int. Cl. H01L 27/108

(52) U.S. Cl. CPC H01L 27/10891; H01L 27/10814; H01L 27/10885; H01L 27/10855

(57) ABSTRACT

One memory cell region includes memory cells that are aligned in a first direction and a second direction orthogonal to the first direction, a word line contact region adjacent to the memory cell region in the first direction interposed by a dummy pattern region, and first and second word lines that span a plurality of active regions aligned in the first direction and extend from the memory cell region to the word line contact region. A first word line and a second word line adjacent to each other within one active region located in the memory cell region constitute a word line pair. A gap in the second direction between a first word line and a second word line that constitute a word line pair in the memory cell region is narrower than a gap in the second direction in the word line contact region.

### TECHNICAL FIELD

The present invention relates to a semiconductor device and to a method for manufacturing same.

### BACKGROUND

A dynamic random access memory (DRAM) is one type of semiconductor device. A DRAM comprises a plurality of word lines extending in a first direction and a plurality of bit lines extending in a second direction intersecting the first direction. The DRAM has a structure in which a memory cell is located at the intersection of a word line and a bit line.

JP 10-173153 A (Patent Document 1) describes an exemplary DRAM configuration in which word lines and bit lines extend in orthogonal directions.

### Patent Document

Patent Document 1: JP 10-173153 A

### SUMMARY OF THE INVENTION

### Problem to be Solved by the Invention

There are various types of DRAM memory cell configurations, one of which is an active-region orthogonal-arrangement configuration in which a plurality of active regions forming part of a memory cell are aligned in the X-direction and in the Y-direction orthogonal to the X-direction. As shown in FIG. 10A and FIG. 10B, two word lines (WL1, WL2) extend across a plurality of active regions 100A which are aligned in one direction. That is to say, two word lines (WL1, WL2) intersecting one active region 100A constitute a word line pair. Each word line pair is extended to a word line contact region WC located in an element isolation region peripheral to a memory mat in order to connect to a sub-word driver (SWD).

A word line contact plug 1 connected to the upper surface of one word line out of the word line pair is provided in the word line contact region WC. The word line contact plug 1 is further connected to the sub-word driver (SWD) by means of peripheral wiring 200 which is connected to the upper surface of the word line contact plug 1.

With this configuration, however, the interval D2a between the two word lines forming the word line pair is narrow, so a problem arises if the semiconductor device is miniaturized in that short-circuiting occurs between the word line contact plug 1 disposed on the upper surface of one of the word lines WL2 and the other word line WL1 forming the word line pair.

The present invention provides a semiconductor device which can avoid short circuiting between a word line contact plug and an adjacent word line, and a method for manufacturing same.

### Means for Solving the Problem

A semiconductor device according to one mode of the present invention is characterized in that it comprises:

a memory cell region in which memory cells are aligned on a semiconductor substrate in a first direction and a second direction orthogonal to the first direction;
a word line contact region adjacent to the memory cell region in the first direction with a dummy pattern region therebetween; and
a first word line and a second word line which extend from the memory cell region to the word line contact region across a plurality of active regions aligned in the first direction,
the first word line and the second word line which are adjacent within one active region located in the memory cell region forming a word line pair, and
the interval in the second direction in the memory cell region between the first word line and the second word line forming the word line pair being narrower than the interval in the second direction in the word line contact region.

A semiconductor device according to another mode of the present invention is characterized in that it comprises:

a memory cell region in which memory cells are aligned on a semiconductor substrate in a first direction and a second direction orthogonal to the first direction;
a word line contact region adjacent to the memory cell region in the first direction with a dummy pattern region therebetween; and
a first word line and a second word line which extend from the memory cell region to the word line contact region across a plurality of active regions aligned in the first direction,
the first word line and the second word line which are adjacent within one active region located in the memory cell region forming a word line pair,
the first word line and the second word line located in the memory cell region and the word line contact region being formed by straight lines extending in the first direction, and
the first word line and the second word line located in the dummy pattern region being formed by straight lines which are inclined in the first direction in such a way that the width increases from the memory cell region toward the word line contact region.

Furthermore, a method for manufacturing a semiconductor device according to one mode of the present invention is characterized in that it comprises the following steps:

a step in which a memory cell region is formed on a semiconductor substrate in such a way that memory cells are aligned in a first direction and a second direction orthogonal to the first direction;
a step in which a dummy pattern region is formed;
a step in which a word line contact region adjacent to the memory cell region in the first direction is formed with the dummy pattern region therebetween;
a step in which a plurality of active regions are formed in such a way as to be aligned in the first direction; and
a step in which a first word line and a second word line are formed in such a way as to extend from the memory cell region to the word line contact region across the plurality of active regions,
the first word line and the second word line which are adjacent within one active region located in the memory cell region forming a word line pair,
the first word line and the second word line located in the memory cell region and the word line contact region being formed by straight lines extending in the first direction, and
the first word line and the second word line located in the dummy pattern region being formed by straight lines which are inclined in the first direction in such a way that the width increases from the memory cell region toward the word line contact region.

### Advantage of the Invention

According to the present invention, it is possible to avoid short circuiting between a word line contact plug and an adjacent word line.

### BRIEF DESCRIPTION OF THE FIGURES

FIG. 1A is a view in the cross section A-A in FIG. 1C of a semiconductor device according to a mode of embodiment of the present invention;

FIG. 1B is a view in the cross section B-B in FIG. 1C of the semiconductor device according to a mode of embodiment of the present invention;

FIG. 1C is a plan view of the semiconductor device according to a mode of embodiment of the present invention;

FIG. 1E shows part of the planar configuration of the semiconductor device according to a mode of embodiment of the present invention;

FIG. 2A is a view in cross section to illustrate a method for manufacturing the semiconductor device according to a mode of embodiment of the present invention;

FIG. 2B is a view in cross section to illustrate the method for manufacturing the semiconductor device according to a mode of embodiment of the present invention;

FIG. 2C is a plan view to illustrate the method for manufacturing the semiconductor device according to a mode of embodiment of the present invention;

FIG. 3A is a view in cross section to illustrate the method for manufacturing the semiconductor device according to a mode of embodiment of the present invention;

FIG. 3B is a view in cross section to illustrate the method for manufacturing the semiconductor device according to a mode of embodiment of the present invention;

FIG. 3C is a plan view to illustrate the method for manufacturing the semiconductor device according to a mode of embodiment of the present invention;

FIG. 4A is a view in cross section to illustrate the method for manufacturing the semiconductor device according to a mode of embodiment of the present invention;

FIG. 4B is a view in cross section to illustrate the method for manufacturing the semiconductor device according to a mode of embodiment of the present invention;

FIG. 4C is a plan view to illustrate the method for manufacturing the semiconductor device according to a mode of embodiment of the present invention;

FIG. 5C is a plan view to illustrate the method for manufacturing the semiconductor device according to a mode of embodiment of the present invention;

FIG. 6A is a view in cross section to illustrate the method for manufacturing the semiconductor device according to a mode of embodiment of the present invention;

FIG. 6B is a view in cross section to illustrate the method for manufacturing the semiconductor device according to a mode of embodiment of the present invention;

FIG. 6C is a plan view to illustrate the method for manufacturing the semiconductor device according to a mode of embodiment of the present invention;

FIG. 7A is a view in cross section to illustrate the method for manufacturing the semiconductor device according to a mode of embodiment of the present invention;

FIG. 7B is a view in cross section to illustrate the method for manufacturing the semiconductor device according to a mode of embodiment of the present invention;

FIG. 7C is a plan view to illustrate the method for manufacturing the semiconductor device according to a mode of embodiment of the present invention;

FIG. 8A is a view in cross section to illustrate the method for manufacturing the semiconductor device according to a mode of embodiment of the present invention;

FIG. 8B is a view in cross section to illustrate the method for manufacturing the semiconductor device according to a mode of embodiment of the present invention;

FIG. 8C is a plan view to illustrate the method for manufacturing the semiconductor device according to a mode of embodiment of the present invention;

FIG. 9A is a view in cross section to illustrate the method for manufacturing the semiconductor device according to a mode of embodiment of the present invention;

FIG. 9B is a view in cross section to illustrate the method for manufacturing the semiconductor device according to a mode of embodiment of the present invention;

FIG. 10A is a plan view to illustrate the overall arrangement configuration in a conventional semiconductor device; and

FIG. 10B is a plan view showing an enlargement of the portion R in FIG. 10A.

### MODE OF EMBODIMENT OF THE INVENTION

A preferred mode of embodiment of the present invention will be described in detail below with reference to the figures.

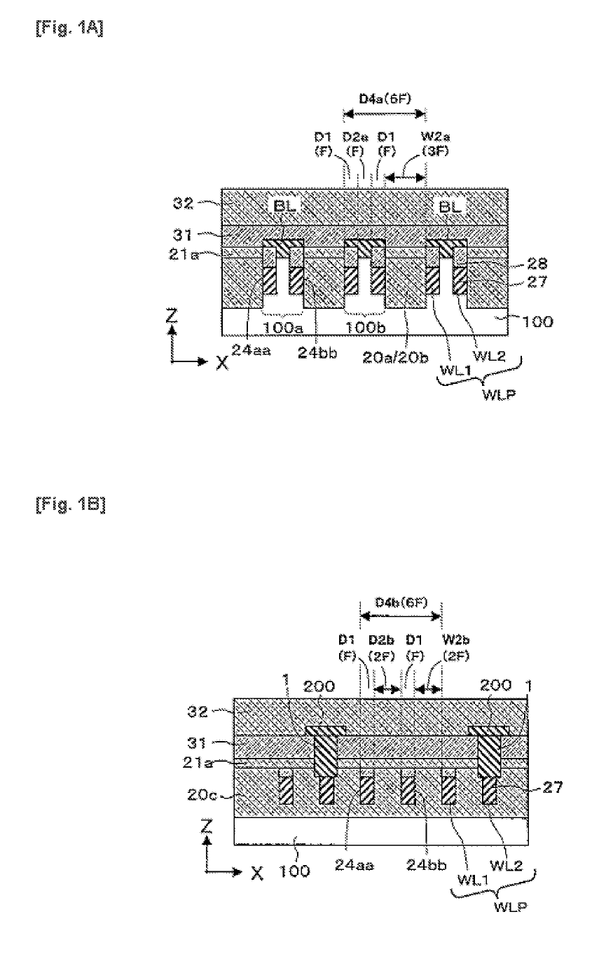

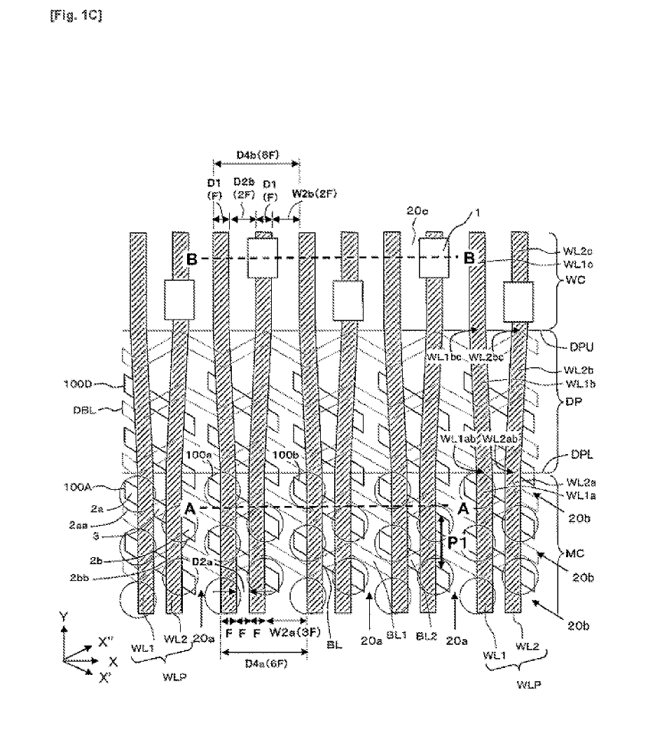

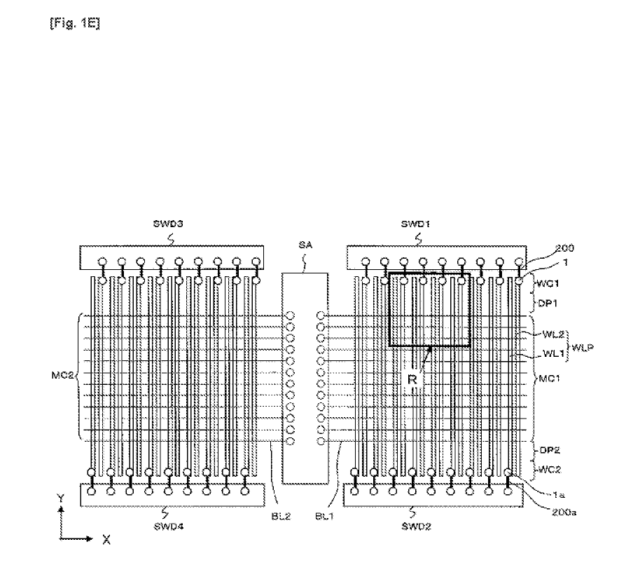

The semiconductor device according to a mode of embodiment of the present invention will be described with the aid of FIG. 1A, FIG. 1B, FIG. 1C and FIG. 1E. Here, FIG. 1E is a general view of the basic arrangement structure of a dynamic random access memory (DRAM) serving as a semiconductor device. FIG. 1C is an enlarged plan view within the thick-lined box R shown in FIG. 1E. FIG. 1A is a view in cross section along the line A-A shown in FIG. 1C, and FIG. 1B is a view in cross section along the line B-B shown in FIG. 1C.

FIG. 1E will be referred to first of all. FIG. 1E shows part of the planar configuration of the semiconductor device according to this mode of embodiment. The basic planar configuration shown in FIG. 1E comprises a plurality of arrangements in the X-direction and the Y-direction in order to form the DRAM. A plurality of bit lines BL1 which are connected to a sense amplifier SA located in the center and extend in the X-direction (second direction) on the right are provided. A plurality of word line pairs WLP are provided in the Y-direction (first direction) orthogonal to the direction of extension of the bit lines BL1.

The word line pairs WLP comprise a first word line WL1 and a second word line WL2. A memory cell (not depicted) is disposed at the intersection between each word line and each bit line BL1. A first memory cell region MC1 is formed by a plurality of memory cells disposed in the form of a matrix. A first word line contact region WC1 and a second word line contact region WC2 are provided at both ends of the first memory cell region MC1 in the direction of extension of the word lines, with a first dummy pattern region DP1 and a second dummy pattern region DP2 therebetween. A first sub-word driver circuit SWD1 and a second sub-word driver circuit SWD2 are disposed around the first word line contact region WC1 and the second word line contact region WC2, respectively.

In this mode of embodiment, a first word contact plug 1 for the second word line WL2 forming part of the plurality of word line pairs WLP is disposed in the first word line contact region WC1. A second word contact plug 1a for the first word line WL1 is disposed in the second word line contact region WC2 located on the opposite side. First peripheral wiring 200 and second peripheral wiring 200a are connected to the contact plug 1 and the contact plug 1a, respectively, and are further connected to the first sub-word driver circuit SWD1 and the second sub-word driver circuit SWD2, respectively. It should be noted that a second memory cell region MC2 located on the opposite side to the first memory cell region MC1 with respect to the sense amplifier SA also has the same structure.

The configuration of this mode of embodiment will be described below with the aid of FIG. 1C which is an enlarged plan view of the portion shown by the thick-lined box R in FIG. 1E. FIG. 1C shows part of the arrangement of a DRAM having a plurality of word lines extending in the Y-direction (first direction) and a plurality of bit lines extending in the X-direction (second direction) orthogonal to the direction of extension of the word lines. The bit lines BL extend generally in the X-direction (second direction) while bending back and forth in a snake pattern.

The semiconductor device according to this mode of embodiment comprises at least: a memory cell region MC in which are disposed a plurality of active regions 100A comprising the semiconductor substrate 100; a word line contact region WC in which the word line contact plug 1 is disposed on the word lines WL arranged extending in the Y-direction; and a dummy pattern region DP located between the memory cell region MC and the word line contact region WC. A sub-word driver circuit is further provided on the opposite side of the word line contact region WC to the dummy pattern region DP.

The active regions 100A are arranged in a regular manner aligned in the Y-direction and the X-direction in the memory cell region MC. The individual active regions 100A are enclosed by a first element isolation region 20a extending in the Y-direction, and a second element isolation region 20b extending in the X′-direction (third direction) which is inclined at a positive angle in the X-direction. As a result, the active regions 100A comprise islands which extend in the X′-direction and have the shape of a parallelogram in plan view. The first word line WL1 and the second word line WL2 extending in the Y-direction are disposed across the plurality of active regions 100A aligned in the Y-direction.

As shown in FIG. 1A, the word line WL is formed as an embedded word line which is embedded within the semiconductor substrate 100. The first word line WL1 and the second word line WL2 which are disposed within one active region form a word line pair WLP. Word line pairs WLP are likewise also formed in the other active regions 100A. A word line pair WLP is provided in one active region 100A, and as a result each active region is divided into five regions, namely: a first capacitor contact region 2a, the first word line WL1 adjacent to the first capacitor contact region 2a, a bit line contact region 3 adjacent to the first word line WL1, the second word line WL2 adjacent to the bit line contact region 3, and a second capacitor contact region 2b adjacent to the second word line WL2. A first capacitor 2aa is disposed on the first capacitor contact region 2a, and a second capacitor 2bb is disposed on the second capacitor contact region 2b.

Meanwhile, the bit lines BL are disposed on the bit line contact regions 3. The bit lines BL which extend in the X-direction and are connected to the plurality of bit line contact regions 3 that are adjacent in the X-direction comprise a first bit line BL1 extending in the X′-direction parallel to the active regions 100A, and a second bit line BL2 extending in the X″-direction intersecting the active regions 100A over the bit line contact regions 3.

In addition, the bit lines BL are formed by a snake pattern in which the first bit line BL1 and the second bit line BL2 are connected in an alternating arrangement in each active region 100A. That is to say, the bit lines BL extend overall in the X-direction while bending back and forth in the Y-direction. The bit lines BL formed by the snake pattern are such that a connection between the first bit line BL1 and the second bit line BL2 forms a vertex, and the capacitors 2aa, 2bb are disposed between vertices of two bit lines BL adjacent in the Y-direction. As a result, the capacitors as a whole including the capacitors 2aa and 2bb have a closest-packing arrangement.

A dummy active region 100D and a dummy bit line DBL which do not contribute to the operation of the semiconductor device are disposed in the dummy pattern region DP. As will be described later, the semiconductor device according to this mode of embodiment requires the dummy pattern region DP as a region for inclining the word lines extending in the Y-direction. The dummy pattern region DP also contributes to avoiding the optical proximity effect in lithography.

The dummy pattern region DP has one end DPL located on the memory cell region MC side and another end DPU located on the word line contact region WC side, said ends being adjacent in the Y-direction. The interval between one end DPL and the other end DPU is in the range of 2 to 3 times the arrangement pitch P1 of active regions 100A which are adjacent in the Y-direction. Here, there are problems if the abovementioned interval is in a range narrower than twice said arrangement pitch in that it is difficult to form inclined word lines and disconnection occurs. Furthermore, if the interval is greater than three times said arrangement pitch, this hinders miniaturization of the semiconductor device. For this reason, the abovementioned interval is set in the range of 2 to 3 times the arrangement pitch P1 in this mode of embodiment.

The word line contact region WC is disposed in a peripheral element isolation region 20c located around an area adjacent to the dummy pattern region DP. A sub-word driver circuit region which is not depicted is disposed around the word line contact region WC in the Y-direction. The contact plugs 1 to the wiring for connection to the sub-word driver circuit are disposed in the word line contact region WC at the word lines extending from the memory cell region MC to the word line contact region WC.

The word line pairs WLP disposed in the memory cell region MC will be described while focusing on active regions 100a and 100b which are adjacent in the X-direction. A word line pair WLP intersecting one active region 100a and extending in the Y-direction is formed by a first word line WL1 and a second word line WL2. Other word line pairs WLP extending in parallel in the Y-direction also have the same configuration. The widths D1 of the first word line WL1 and the second word line WL2 are equal. Here, each width is set as F. Furthermore, the interval D2a between the first word line WL1 and the second word line WL2 is likewise arranged at F. The interval W2a between word line pairs WLP, i.e. the interval W2a between the second word line WL2 and the first word line WL1 in adjacent word line pairs WLP, is 3F. The interval between other adjacent word line pairs is likewise the same. The arrangement pitch D4a of the word line pairs WLP in the X-direction is therefore 6F.

Meanwhile, the interval D2b between the first word line WL1 and the second word line WL2 extending with the same width as the width D1 (F) in the memory cell region MC is increased to 2F in the word line contact region WC. Furthermore, the interval W2b between word line pairs WLP, i.e. the interval W2b between the second word line WL2 and the first word line WL1 in adjacent word line pairs WLP, is reduced to 2F. The interval between other adjacent word line pairs is likewise the same. The respective intervals (D2b, W2b) between the first word line WL1 and the second word line WL2 arranged in the word line contact region WC are therefore all equal intervals of 2F.

It should be noted that the arrangement pitch D4b of the word line pairs WLP in the X-direction is 6F, the same as in the memory cell region. That is to say, the word line pairs WLP are adapted in such a way that the interval between the first word line WL1 and the second word line WL2 is increased from F in the memory cell region MC to 2F in the word line contact region WC, while the arrangement pitch is maintained in the X-direction.

As mentioned above, the semiconductor device according to this mode of embodiment comprises: the memory cell region MC in which the active regions (100A, 100a, 100b) are arranged on the semiconductor substrate 100 in alignment in the first direction (Y-direction) and the second direction (X-direction) orthogonal to the first direction; the word line contact region WC which is adjacent to the memory cell region MC in the first direction with the dummy pattern region DP therebetween; and the first word line WL1 and the second word line WL2 which extend from the memory cell region MC to the word line contact region WC across the plurality of active regions 100 aligned in the first direction, while the first word line WL1 and the second word line WL2 which are adjacent within one active region 100A located in the memory cell region MC form the word line pair WLP, and the interval D2a in the second direction within the memory cell region between the first word line WL1 and the second word line WL2 forming the word line pairs WLP is narrower than the interval D2b in the second direction in the word line contact region WC.

The respective word lines WL disposed in the memory cell region MC and the word line contact region WC comprise straight lines which all extend in parallel in the Y-direction. A spacing transition region in which the spacing in the X-direction of the word line pairs WLP transitions is required between the memory cell region MC and the word line contact region WC in order to provide word line pairs WLP in which the interval in the X-direction in each region varies across the memory cell region MC and the word line contact region WC which are separated in the Y-direction. In this mode of embodiment, the dummy pattern region DP corresponds to the spacing transition region.

As mentioned above, the dummy pattern region DP comprises a boundary DPL with the memory cell region MC and a boundary DPU with the word line contact region WC. The interval between the boundary DPL and the boundary DPU is in the range of 2 to 3 times the arrangement pitch P1 of the active regions 100A which are adjacent in the Y-direction. By providing the dummy pattern region DP, the first word line WL1 forming part of the word line pair WLP comprises: a first portion WL1a located within the memory cell region MC; a second portion WL1b located within the dummy pattern region DP; and a third portion WL1c located within the word line contact region WC. The second word line WL2 likewise comprises a first portion WL2a, a second portion WL2b and a third portion WL2c.

The first portion WL1a and the third portion WL1c of the first word line WL1 are formed by straight lines extending in the Y-direction, but the second portion WL1b is formed by a straight line which is inclined at a negative angle)(−5° in the Y-direction. Meanwhile, the first portion WL2a and the third portion WL2c of the second word line WL2 are formed by straight lines extending in the Y-direction, but the second portion WL2b is formed by a straight line which is inclined at a positive angle (+5°) in the Y-direction.

As a result, the first word line WL1 and the second word line WL2 located in the dummy pattern region DP are formed by straight lines which are inclined in the first direction in such a way that the width thereof increases from the memory cell region MC toward the word line contact region WC. The second portion WL1b is therefore formed by a parallelogram shape including at least two end faces WL lab and WL1bc in the Y-direction. Furthermore, the second portion WL2b which forms part of the second word line WL2 is likewise formed by a parallelogram shape including at least two end faces WL2ab and WL2bc in the Y-direction.

As mentioned above, the semiconductor device comprises: the memory cell region MC including the active regions (100A, 100a, 100b) which are arranged on the semiconductor substrate 100 in alignment in the first direction and the second direction orthogonal to the first direction; the word line contact region WC which is adjacent to the memory cell region MC in the first direction with the dummy pattern region DP therebetween; and the first word line WL1 and the second word line WL2 which extend from the memory cell region MC to the word line contact region WC across the plurality of active regions 100 aligned in the first direction, while the first word line WL1 and the second word line WL2 which are adjacent within one active region 100 located in the memory cell region MC form the word line pair WLP, first word line WL1 and the second word line WL2 located in the memory cell region MC and the word line contact region WC are formed by straight lines extending in the first direction, and the first word line WL1 and the second word line WL2 located in the dummy pattern region DP are formed by straight lines (WL1b, WL2b) which are inclined in the first direction in such a way that the width thereof increases from the memory cell region MC toward the word line contact region WC.

The first word line WL1 and the second word line WL2 forming the word line pair WLP are arranged with line symmetry about an imaginary centerline extending in the Y-direction through the center in the X-direction lying between the first word line WL1 and the second word line WL2.

The word line contact plug 1 disposed on the respective second word lines WL2 is provided in the word line contact region WC. In this mode of embodiment, the word line contact plug 1 is disposed on the respective second word lines WL2, but it may equally be disposed on the respective first word lines WL1. The word line contact plug 1 is disposed on either of the word lines. A word line contact plug 1 is connected to a word line to which a word line contact plug 1 is not connected in the word line contact region WC located on the opposite side of the memory cell region MC.

The adjacent word line contact plugs 1 are arranged in a staggered manner in the X-direction in the word line contact region WC shown in FIG. 1C. Furthermore, FIG. 1B is a view in the cross section B-B in FIG. 1C. As shown in the cross section of FIG. 1B, the first word line WL1 embedded in a first word trench 24aa arranged within the peripheral element isolation region 20c and the second word line WL2 embedded in a second word trench 24bb are arranged at equal intervals in the X-direction. Within these, the word line contact plug 1 connected to the upper surface of the second word line WL2 is disposed within an interlayer insulating film 31, and the peripheral wiring 200 connected to the upper surface of the word line contact plug 1 is further provided and is connected to a sub-word driver circuit which is not depicted.

FIG. 1A is a view in the cross section A-A in FIG. 1C. As shown in FIG. 1A, the first word line WL1 embedded in the first word trench 24aa the side surface of which is in contact with the element isolation region, and the second word line WL2 embedded in the second word trench 24bb are disposed within each of the active regions 100a, 100b which are located between first and second element isolation regions 20a, 20b, and the bit line BL is connected to the upper surface of a bit contact region 3 between the first word trench 24aa and the second word trench 24bb. Here, the width relationships of the various components described in regard to FIG. 1A and FIG. 1B are the same as in FIG. 1C.

As mentioned above, according to a mode of embodiment of the present invention, the interval between the plurality of word lines is equal in the word line contact region WC, and therefore the interval between the word lines disposed in the word line contact region WC is greater than the interval between the word lines disposed in the memory cell region MC. As a result, it is possible to avoid short circuiting between the word line contact plug 1 and the adjacent word line.

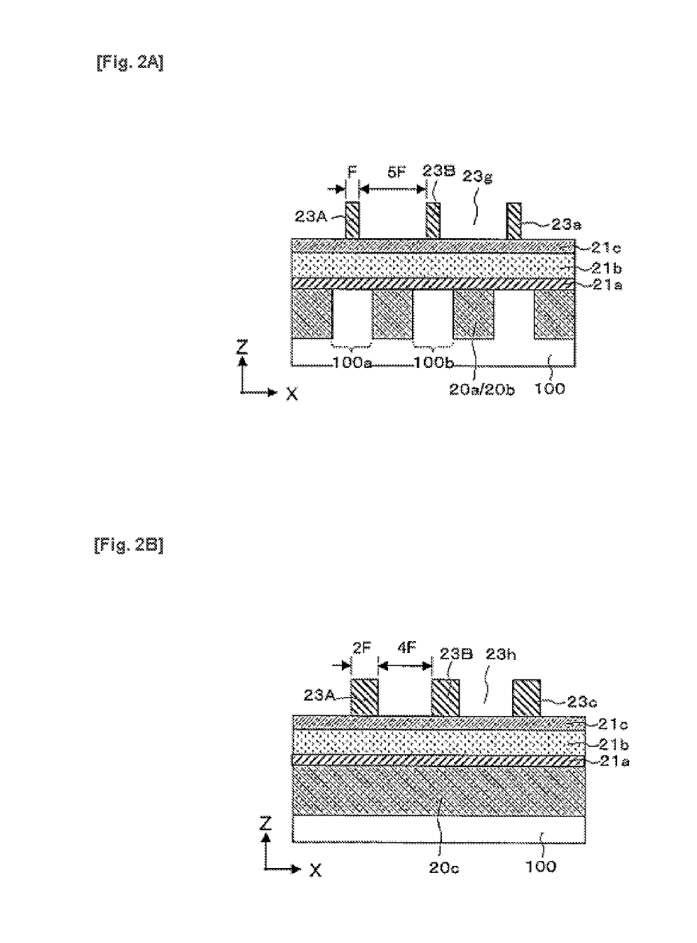

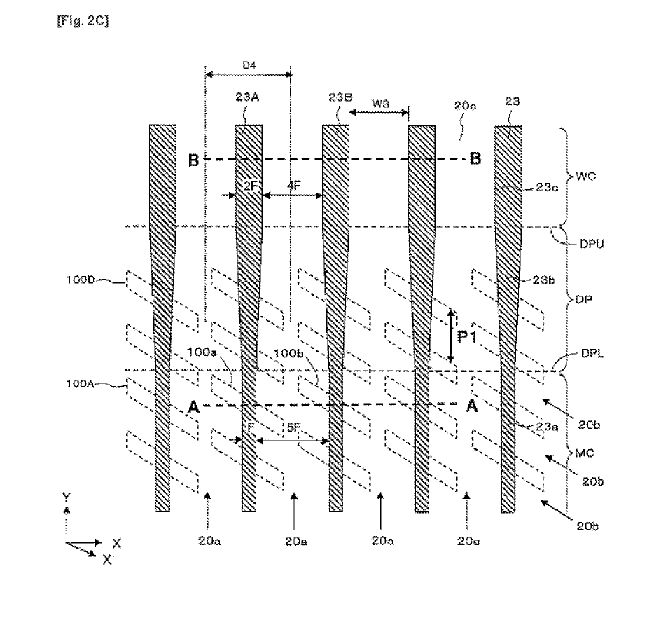

A method for manufacturing a semiconductor device consisting of the abovementioned DRAM will be described next with the aid of FIG. 2 to FIG. 9. It should be noted that each “C” drawing is an enlarged plan view, each “A” drawing is a view in the cross section A-A in the “C” drawing, and each “B” drawing is a view in the cross section B-B in the “C” drawing.

(Active Region Formation Step)

FIG. 2C will be referred to first of all. A plurality of active regions 100A and a plurality of dummy active regions 100D comprising a semiconductor substrate 100 comprising a p-type single-crystal silicon substrate which are enclosed by a first element isolation region 20a extending in the Y-direction (first direction) and a second element isolation region 20b extending in the X′-direction (third direction) are formed by means of known shallow trench isolation (STI) on the semiconductor substrate 100. The dummy active regions 100D constitute active regions which do not function as memory cells.

As a result, a memory cell region MC in which the active regions 100A functioning as memory cells are aligned, a dummy pattern region DP adjacent to the memory cell region MC in the Y-direction, and a word line contact region WC adjacent to the dummy pattern region DP in the Y-direction are formed. The word line contact region WC is set within a peripheral element isolation region 20c. It should be noted that in this mode of embodiment, the active regions 100A must be aligned in the Y-direction and the X-direction (second direction) orthogonal to the Y-direction.

As shown in FIG. 1E, the dummy pattern region DP and the word line contact region WC are formed at both ends of the memory cell region MC in the Y-direction, but since both ends have the same structure, the following description will focus only on the upper end.

The width of the dummy pattern region DP in the Y-direction is within the range of 2 to 3 times the arrangement pitch P1 of the active regions 100A which are adjacent in the Y-direction. The dummy pattern region DP comprises a lower end DPL at the boundary with the memory cell region MC and an upper end DPU at the boundary with the word line contact region WC. The distance between the lower end DPL and the upper end DPU is equal to the width of the dummy pattern region DP in the Y-direction. Furthermore, the width of the word line contact region WC in the Y-direction is within the range of 3 to 5 times the arrangement pitch P1 of the active regions 100A which are adjacent in the Y-direction.

(First Pattern Formation Step)

FIG. 2A and FIG. 2B will be referred to next. Here, 100a, 100b are the two active regions which are adjacent in the X-direction and intersect the line of the cross section A-A in FIG. 2C. After formation of the active regions 100a, 100b which are surrounded by the first element isolation region 20a and the second element isolation region 20b, a first mask film 21a comprising a silicon nitride film having a thickness of 40 nm is formed over the whole surface by means of plasma CVD.

A second mask film 21b comprising an amorphous carbon film having a thickness of 150 nm is then formed by means of plasma CVD. A third mask film 21c comprising a silicon dioxide film having a thickness of 40 nm is then formed as a lamination by means of plasma CVD.

A first pattern 23 comprising a photoresist is then formed on the third mask film 21c by means of lithography. Here, for the sake of convenience in the description, individual first patterns 23A, 23B extending in the Y-direction from the memory cell region MC across the word line contact region WC are indicated, as shown in FIG. 2C. Furthermore, the first pattern formed on the memory cell region MC is denoted the MC first pattern 23a, the first pattern formed on the dummy pattern region DP is denoted the DP first pattern 23b, and the WC first pattern formed on the word line contact region WC is denoted 23c.

FIG. 2A shows a cross section of the MC first pattern 23a formed on the memory cell region MC. The width of the MC first pattern 23a in the X-direction is F, and the interval between adjacent MC first patterns 23a is 5F. The arrangement pitch of the MC first pattern 23a is therefore 6F. By forming the MC first pattern 23a, the MC first recess 23g having a width of 5F in the X-direction is formed in the memory cell region MC. It should be noted that in this mode of embodiment, F is set at 20 nm, for example.

FIG. 2B shows the cross section of the WC first pattern 23c formed on the word line contact region WC. The width of the WC first pattern 23c in the X-direction is 2F, and the interval between adjacent WC first patterns 23c is 4F. The arrangement pitch of the WC first pattern is therefore 6F. By providing the WC first pattern 23c, the WC first recess 23h having a width of 4F in the X-direction is formed in the word line contact region WC. The MC first pattern 23a and the WC first pattern 23c are both formed as rectangular shapes extending in the Y-direction.

Meanwhile, the DP first pattern 23b which is formed on the dummy pattern region DP is formed as an inverted trapezium shape with left/right symmetry where the upper base is 2F and the lower base is F. That is to say, the DP first pattern 23b is formed as an inverted trapezium shape in which the interval of the facing side surfaces continuously increases in such a way that the width doubles in the X-direction from the memory cell region MC side toward the word line contact region WC side.

(Sacrificial Film Formation Step)

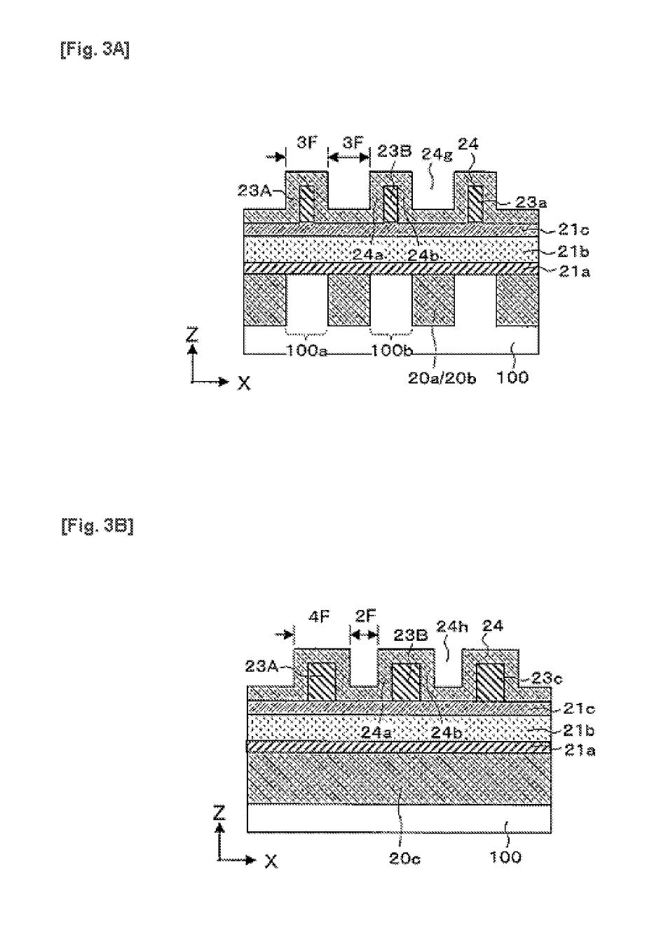

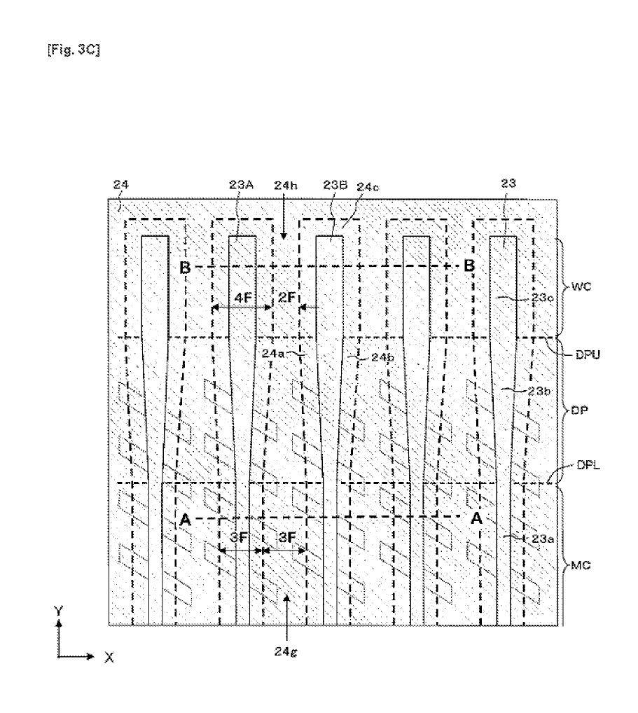

FIG. 3A to FIG. 3C will be referred to next. The first pattern 23 comprising a photoresist is formed, after which a first sacrificial film 24 comprising a silicon dioxide film having a thickness F is formed over the whole surface in such a way as to cover the first pattern 23. The first sacrificial film 24 which is formed on the surface of the photoresist having poor heat resistance is formed using molecular layer deposition (MLD) which enables film formation at low temperature (up to 100° C.). As a result, a new MC second recess 24g having a width of 3F in the X-direction is formed within the MC first recess 23g. A new WC second recess 24h having a width of 2F in the X-direction is formed within the WC first recess 23h.

Furthermore, the first sacrificial film 24 is formed in such a way as to surround the peripheral side surfaces of the first patterns 23A and 23B, and comprises a pair of side-surface side walls 24a, 24b which are formed along two side surfaces which are facing in the X-direction. An end-surface side wall 24c which is formed on the Y-direction end-section side surfaces of the first patterns 23A, 23B is further formed.

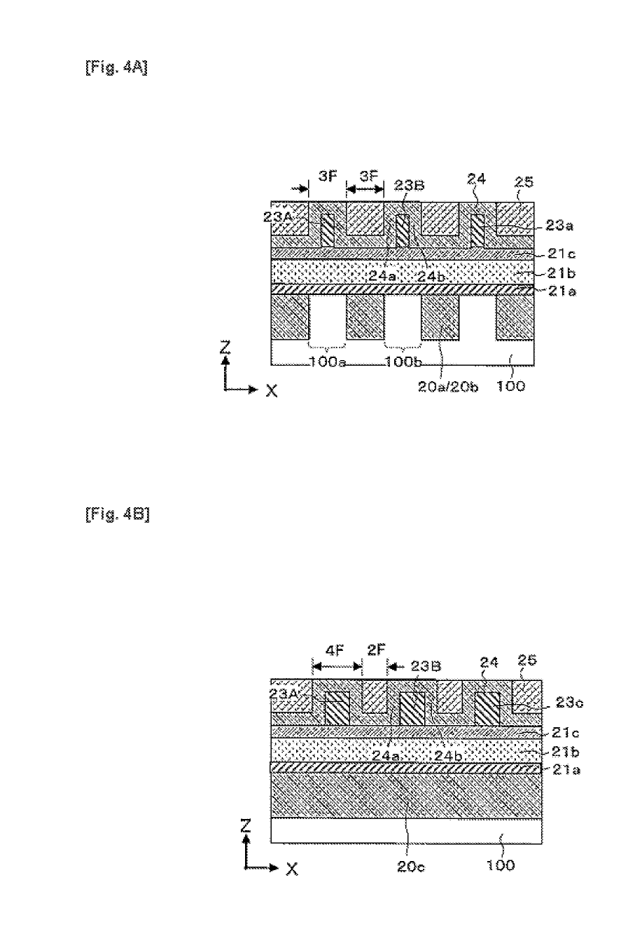

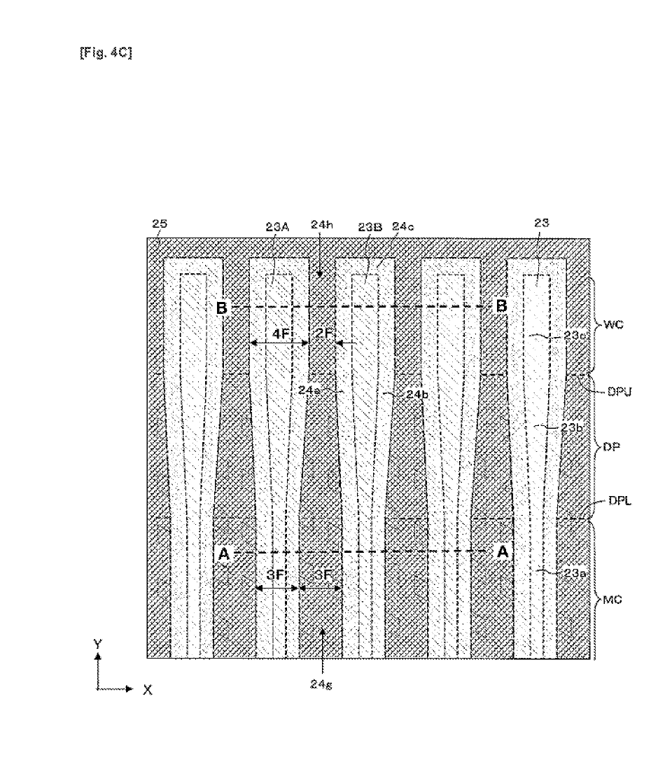

FIG. 4A to FIG. 4C will be referred to next. A second sacrificial film 25 comprising an organic film is formed by means of spin coating in such a way as to fill all of the recesses formed on the surface, in addition to the MC second recess 24g and the WC second recess 24h. After this, the second sacrificial film 25 formed on the upper surface of the first sacrificial film 24 is removed in order to expose the upper surface of the first sacrificial film 24.

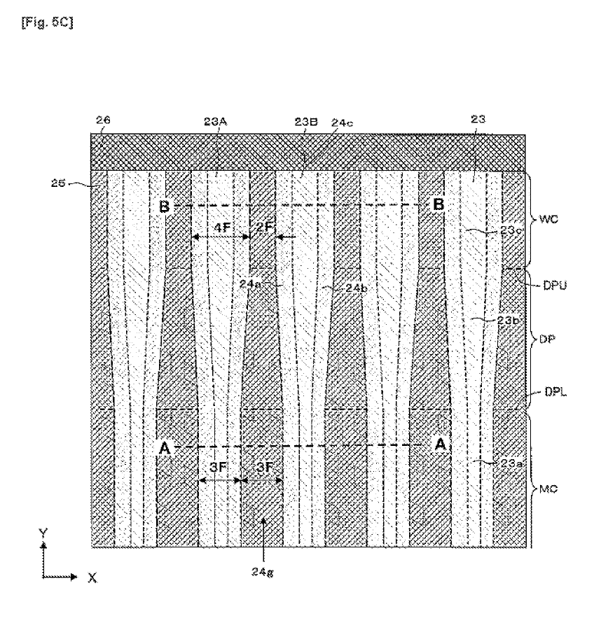

FIG. 5C will be referred to next. Here, the “A” and “B” drawings are the same as FIG. 4A and FIG. 4B, and are therefore omitted. A third sacrificial film 26 comprising a photoresist extending in the X-direction and covering a peripheral circuit region is formed by means of lithography in such a way as to cover the end-surface side wall 24c formed on the Y-direction end-section side surfaces of the first patterns 23A, 23B at the stage of FIG. 3A to FIG. 3C. The upper surface of the first sacrificial film 24 located in the memory cell region MC, the dummy pattern region DP and the word line contact region WC is exposed as a result.

(Second Pattern Formation Step)

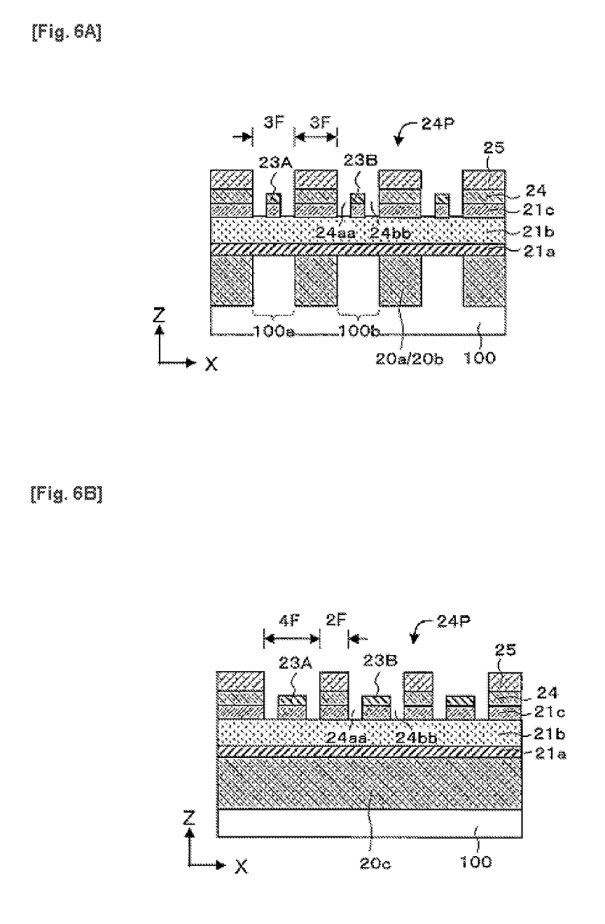

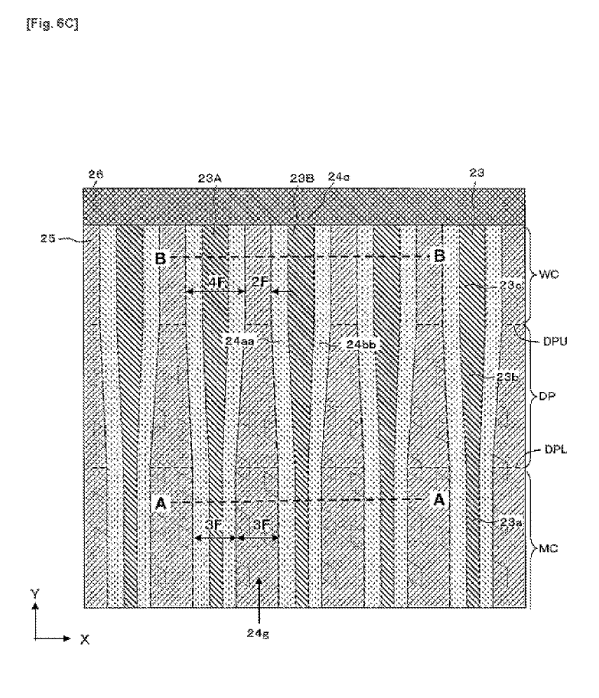

FIG. 6A to FIG. 6C will be referred to next. The first sacrificial film 24 the upper surface of which is exposed is selectively removed using the third sacrificial film 26 and the second sacrificial film 25 as a mask. As a result, the side-surface side walls 24a and 24b formed by the first sacrificial film 24 are removed and a second pattern 24P comprising a first word trench opening 24aa and a second word trench opening 24bb is formed. The first word trench opening 24aa and the second word trench opening 24bb which lie either side of the first patterns 23A and 23B form respective word trench opening pairs.

To describe this in more detail, the first sacrificial film 24 comprises a silicon dioxide film, and when the side-surface side walls 24a and 24b comprising the first sacrificial film are etched, the upper surface of the third mask film 21c is exposed at the bottom surface thereof. The third mask film 21c also comprises a silicon dioxide film, however, so etching is performed continuously and the etching progresses until the upper surface of the second mask film 21b comprising an amorphous carbon film is exposed. As a result, the second pattern 24P is formed comprising the first word trench opening 24aa and the second word trench opening 24bb in which the upper surface of the second mask film 21b comprising an amorphous carbon film is exposed at the bottom surface.

Meanwhile, the end-surface side wall 24c is covered by the third sacrificial film 26 and is therefore not etched. Accordingly, an opening is not formed at the location of the end-surface side wall 24c. If an opening is formed at the location of the end-surface side wall 24c, a situation arises in which the first word trench opening 24aa and the second word trench opening 24bb are connected via the opening formed in the end surface. This creates a problem in that short-circuiting occurs between the first word line WL1 and the second word line WL2 which are formed by filling the word trench openings in a subsequent step.

The interval between the word trench opening pairs forming the second pattern 24P is 3F in the memory cell region MC and 2F in the word line contact region WC. Furthermore, the width in the X-direction of the first word trench opening 24aa and the second word trench opening 24bb forming the word trench opening pairs is F. The intervals between the first word trench opening 24aa and the second word trench opening 24bb are equal intervals of F in the memory cell region MC, equal intervals of 2F in the word line contact region, and unequal intervals varying from F to 2F in the dummy pattern region DP from the memory cell region MC toward the word line contact region WC.

(Second Pattern Transfer and Formation Step)

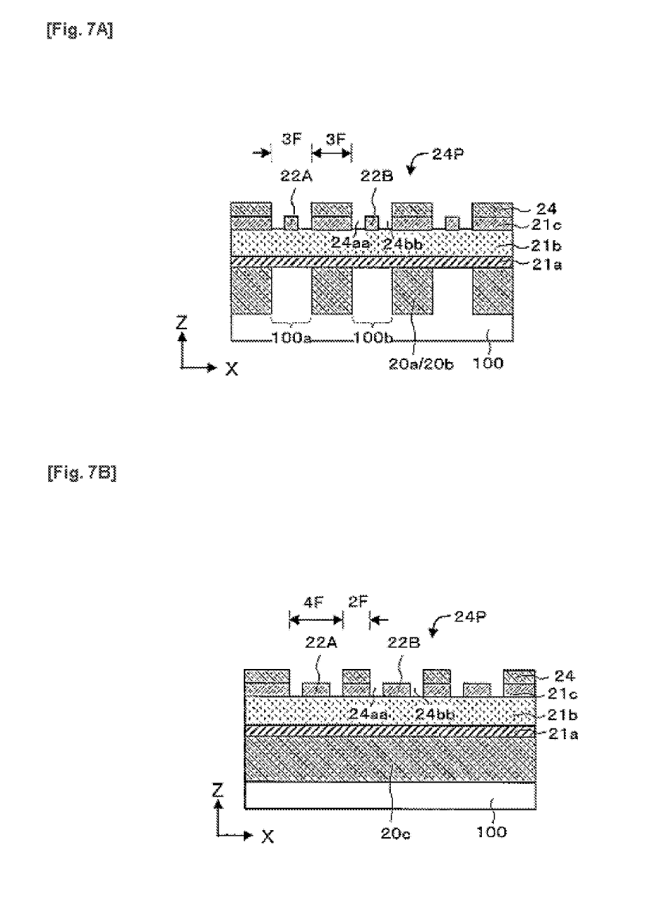

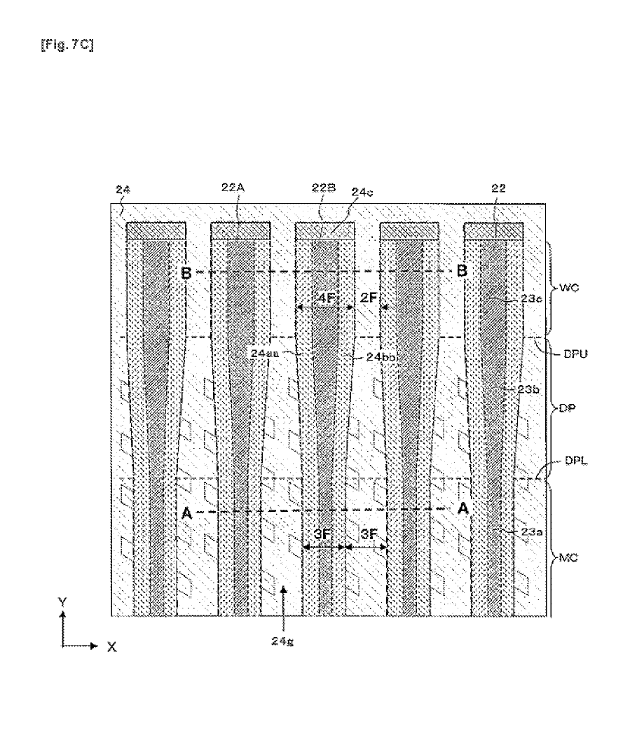

FIG. 7A to FIG. 7C will be referred to next. After the word trench openings 24aa and 24bb have been formed, the third sacrificial film 26, second sacrificial film 25 and first patterns 23A, 23B are removed by means of dry etching employing oxygen plasma. As a result, a situation is produced in which the upper surfaces of the first sacrificial film 24 and the third mask film 21c comprising a silicon dioxide film, and part of the upper surface of the second mask film 21b comprising an amorphous carbon film are exposed.

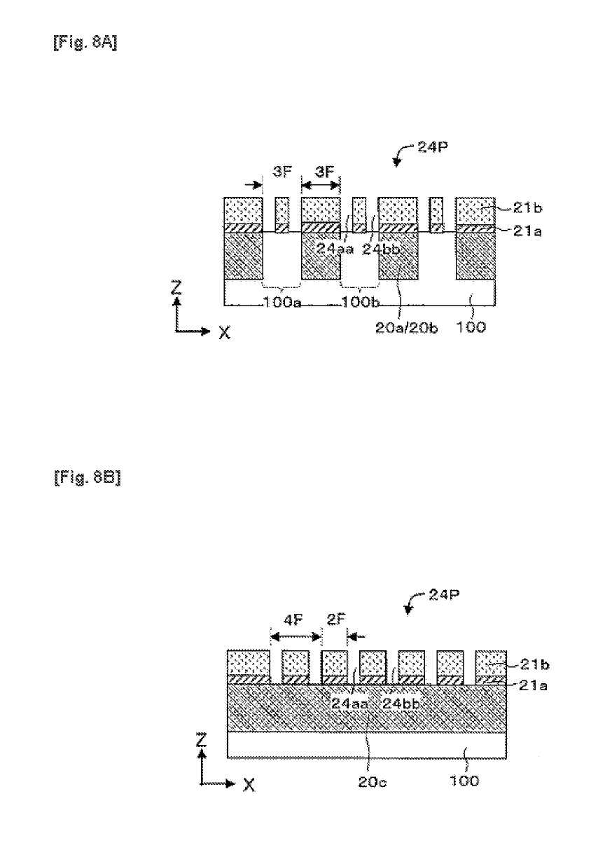

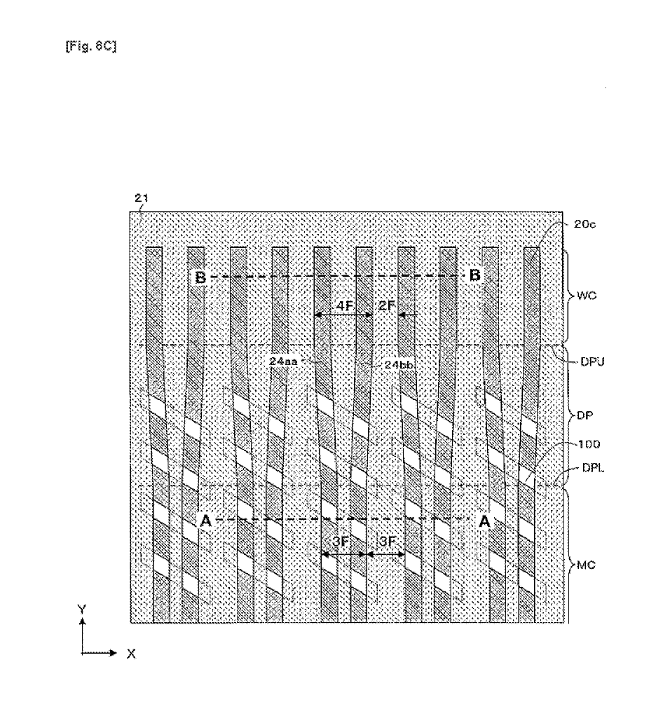

FIG. 8A to FIG. 8C will be referred to next. The second mask film 21b comprising an amorphous carbon film is first of all etched by means of dry etching employing oxygen plasma and using the first sacrificial film 24 and the third mask film 21c comprising a silicon dioxide film as a mask, and the second pattern 24P is transferred to the second mask film 21b. As a result, the upper surface of the first mask film 21a comprising a silicon nitride film is exposed at the bottom surfaces of the first word trench opening 24aa and the second word trench opening 24bb.

The first sacrificial film 24 and the third mask film 21c which were employed as a mask are then removed by means of a hydrofluoric acid (HF)-containing solution. The first mask film 21a comprising a silicon nitride film is not removed by the HF-containing solution. The end-surface side wall 24c remaining on the Y-direction end-section side surfaces of the first patterns 23A, 23B is also removed as a result. The first mask film is then etched by means of dry etching using the second mask film 21b as a mask, and the second pattern 24P is transferred to the first mask film 21a. As a result, the upper surface of an active region 100 is exposed in the portion intersecting an active region 100 at the bottom surfaces of the first word trench opening 24aa and the second word trench opening 24bb, and the upper surfaces of the second element isolation region 20b and the peripheral element isolation region 20c are exposed at another bottom surface.

(Word Trench Formation Step)

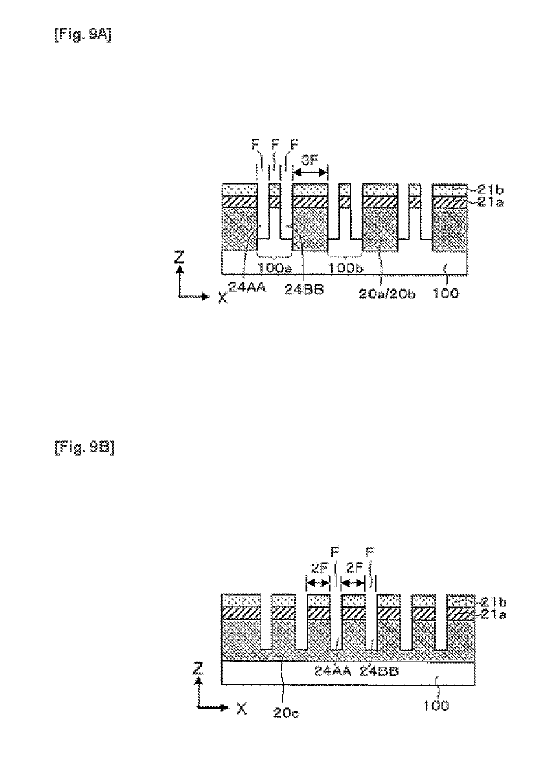

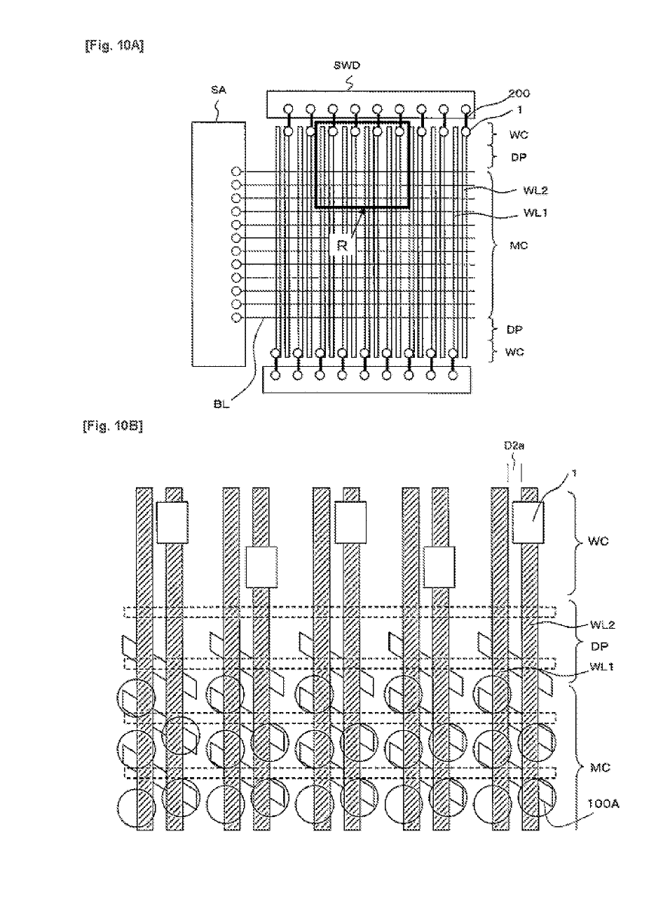

FIG. 9A and FIG. 9B will be referred to next. Here, the “C” drawing is the same as FIG. 8C and is therefore omitted. The element isolation regions 20b, 20c and the active regions 100a, 100b the upper surfaces of which are exposed are etched by means of dry etching using the second mask film 21b and the first mask film 21a as a mask, and a first word trench 24AA and a second word trench 24BB are formed.

The second mask film 21b is then removed, after which the semiconductor device which is constructed as a DRAM can be manufactured via the following steps, as shown in FIG. 1A and FIG. 1B: a step in which a gate insulating film is formed on the inner surfaces of the word trenches; a step in which the gate insulating film is covered, the lower part of the first word trench 24AA and the lower part of the second word trench 24BB are filled by a conductor 27, and the first word line WL1 and the second word line WL2 are formed; a step in which a cap insulating film 28 covering the upper surface of the word lines is formed; a step in which bit lines BL having a snake pattern in plan view are formed; a step in which a first interlayer insulating film 31 is formed; a step in which word line contact plugs 1 are formed in the word line contact region WC; a step in which peripheral wiring 200 for connecting the word lines to a sub-word driver is formed; a step in which a second interlayer insulating film 32 is formed; a step in which capacitor contact plugs which are not depicted are formed on capacitor contact regions 2a, 2b; a step in which capacitors 2aa, 2bb connecting to the capacitor contact plugs are formed; a step in which a third interlayer insulating film is formed; and a step in which upper-layer wiring is formed.

The method for manufacturing a semiconductor device according to this mode of embodiment employs a double patterning method having an arrangement in which the X-direction width in the memory cell region MC is less than the X-direction width in the word line contact region WC, and the first pattern 23 constituting a core is formed continuously in the Y-direction, after which the sacrificial film formed along the side surface of the first pattern 23 is selectively removed to form the second pattern 24P, and therefore it is possible to form a second pattern film 24P in a self-aligning manner with respect to the first pattern 23.

By forming the width of each region of the first pattern 23 to a predetermined width, it is possible to form word lines formed at unequal pitch intervals in the X-direction in the memory cell region MC as word lines having an equal pitch interval in the X-direction in the word line contact region WC. As a result, the word line interval in the word line contact region WC is increased, so it is possible to avoid short circuiting between the word line contact plug 1 and the adjacent word line.

A preferred mode of embodiment of the present invention was described above, but the present invention is not limited to the abovementioned mode of embodiment and various modifications are possible within a scope that does not depart from the essential point of the present invention, and it goes without saying that any such modifications are also included in the scope of the present invention.

This application claims the benefit of priority on the basis of Japanese Patent Application 2013-61501 filed on Mar. 25, 2013, the disclosure of which is hereby incorporated in its entirety as a reference document.

### Key to Symbols

1 . . . First word contact plug
1a . . . Second word contact plug
2a . . . First capacitor contact region
2aa . . . First capacitor
2b . . . Second capacitor contact region
2bb . . . Second capacitor
20a . . . First element isolation region
20b . . . Second element isolation region
20c . . . Peripheral element isolation region
21a . . . First mask film
21b . . . Second mask film
21c . . . Third mask film
23 . . . First pattern
23a . . . MC first pattern
23b . . . DP first pattern
23c . . . WC first pattern
23g . . . MC first recess
23h . . . WC first recess
24 . . . First sacrificial film
24aa . . . First word trench
24bb . . . Second word trench
24a . . . Side-surface side wall
24b . . . Side-surface side wall
24c . . . Side-surface side wall
24g . . . MC second recess
24h . . . WC second recess
25 . . . Second sacrificial film
26 . . . Third sacrificial film
28 . . . Cap insulating film
3 . . . Bit line contact region
31 . . . First interlayer insulating film
32 . . . Second interlayer insulating film
100 . . . Semiconductor substrate
100A . . . Active region
100a . . . Active region
100b . . . Active region
100D . . . Dummy active region
200 . . . First peripheral wiring
200a . . . Second peripheral wiring

1. A semiconductor device comprising:
a memory cell region in which memory cells are aligned on a semiconductor substrate in a first direction and a second direction orthogonal to the first direction;
a word line contact region adjacent to the memory cell region in the first direction with a dummy pattern region therebetween; and
a first word line and a second word line which extend from the memory cell region to the word line contact region across a plurality of active regions aligned in the first direction, wherein the first word line and the second word line are adjacent within one active region located in the memory cell region forming a word line pair, and the interval in the second direction in the memory cell region between the first word line and the second word line forming the word line pair being narrower than the interval in the second direction in the word line contact region.

2. The semiconductor device as claimed in claim 1, wherein the interval in the second direction in the memory cell region between the first word line and the second word line forming the word line pair is half of the interval in the second direction in the word line contact region.

3. The semiconductor device as claimed in claim 2, wherein, if the minimum processing dimension is F, the interval in the second direction in the memory cell region between the first word line and the second word line forming the word line pair is F, and the interval in the second direction in the word line contact region is 2F.

4. The semiconductor device as claimed in claim 3, wherein the arrangement pitch of the word line pair in the second direction in the memory cell region and the arrangement pitch of the word line pair in the second direction in the word line contact region are equal.

5. The semiconductor device as claimed in claim 4, wherein the arrangement pitch of the word line pair in the second direction is 6F.

6. The semiconductor device as claimed in claim 1, wherein a plurality of the first word lines and a plurality of the second word lines disposed in the memory cell region are arranged with an unequal pitch interval in the second direction, and a plurality of the first word lines and a plurality of the second word lines disposed in the word line contact region are arranged with an equal pitch interval in the second direction.

7. The semiconductor device as claimed in claim 1, wherein the first word line and the second word line forming the word line pair are arranged with line symmetry about a centerline located therebetween and extending in the first direction.

8. The semiconductor device as claimed in claim 1, wherein the interval of the dummy pattern region in the first direction is 2 to 3 times the arrangement pitch of the active regions which are adjacent in the first direction.

9. The semiconductor device as claimed in claim 1, comprising a word line contact plug disposed on either the first word line or the second word line in the word line contact region.

10. The semiconductor device as claimed in claim 9, wherein the word line contact plugs are arranged in a staggered manner in the second direction.

11. The semiconductor device as claimed in claim 1, wherein one active region comprises:
a bit line contact region located between the first word line and the second word line; and
a bit line connected to the plurality of bit line contact regions adjacent in the second direction and extending in the second direction comprises a first bit line extending parallel to the active region and a second bit line extending over the bit line contact region while intersecting the active region;
wherein the bit line is formed by a snake pattern in which the first bit line and the second bit line are connected in an alternating arrangement in each active region.

12. The semiconductor device as claimed in claim 11, wherein the bit line formed by the snake pattern is such that a connection between the first bit line and the second bit line has a vertex, a capacitor is disposed between vertices of two bit lines adjacent in the first direction, and the capacitor has a closest-packing arrangement.

13. A semiconductor device comprising:
a memory cell region in which memory cells are aligned on a semiconductor substrate in a first direction and a second direction orthogonal to the first direction;
a word line contact region adjacent to the memory cell region in the first direction with a dummy pattern region therebetween; and
a first word line and a second word line which extend from the memory cell region to the word line contact region across a plurality of active regions aligned in the first direction, wherein:
the first word line and the second word line which are adjacent within one active region located in the memory cell region forming a word line pair;
the first word line and the second word line located in the memory cell region and the word line contact region being formed by straight lines extending in the first direction; and
the first word line and the second word line located in the dummy pattern region being formed by straight lines which are inclined in the first direction in such a way that the width increases from the memory cell region toward the word line contact region.

14. The semiconductor device as claimed in claim 13, wherein a plurality of the first word lines and a plurality of the second word lines disposed in the memory cell region are arranged with an unequal pitch interval in the second direction, and a plurality of the first word lines and a plurality of the second word lines disposed in the word line contact region are arranged with an equal pitch interval in the second direction.

15. The semiconductor device as claimed in claim 13, wherein the interval of the dummy pattern region in the first direction is 2 to 3 times the arrangement pitch of the active regions which are adjacent in the first direction.

16. The semiconductor device as claimed in claim 13, wherein the first word line and the second word line forming the word line pair are arranged with line symmetry about a centerline located therebetween and extending in the first direction.

17. The semiconductor device as claimed in, claim 13 comprising a word line contact plug disposed on either the first word line or the second word line in the word line contact region.

18. The semiconductor device as claimed in claim 17, wherein the word line contact plugs are arranged in a staggered manner in the second direction.

19. The semiconductor device as claimed in claim 13, wherein one active region comprises:
a bit line contact region located between the first word line and the second word line; and
a bit line connected to the plurality of bit line contact regions adjacent in the second direction and extending in the second direction comprises a first bit line extending parallel to the active region and a second bit line extending over the bit line contact region while intersecting the active region;
wherein the bit line is formed by a snake pattern in which the first bit line and the second bit line are connected in an alternating arrangement in each active region.

20. The semiconductor device as claimed in claim 19, wherein the bit line formed by the snake pattern is such that a connection between the first bit line and the second bit line has a vertex, a capacitor is disposed between vertices of two bit lines adjacent in the first direction, and the capacitor has a closest-packing arrangement.

21. A method for manufacturing a semiconductor device, comprising:
forming a memory cell region on a semiconductor substrate in such a way that memory cells are aligned in a first direction and a second direction orthogonal to the first direction;
forming a dummy pattern region;
forming a word line contact region adjacent to the memory cell region in the first direction with the dummy pattern region therebetween;
forming a plurality of active regions in such a way as to be aligned in the first direction; and
forming a first word line and a second word line in such a way as to extend from the memory cell region to the word line contact region across the plurality of active regions, wherein:
the first word line and the second word line which are adjacent within one active region located in the memory cell region forming a word line pair;
the first word line and the second word line located in the memory cell region and the word line contact region being formed by straight lines extending in the first direction; and
the first word line and the second word line located in the dummy pattern region being formed by straight lines which are inclined in the first direction in such a way that the width increases from the memory cell region toward the word line contact region.

22. The method for manufacturing a semiconductor device as claimed in claim 21, comprising:
forming a first pattern which is continuous in the first direction and constitutes a core with an arrangement in which the width of the memory cell region in the second direction is less than the width of the word line contact region in the second direction;
forming a sacrificial film in such a way as to cover the first pattern;
forming a second pattern in a self-aligning manner with respect to the first pattern by selectively removing the sacrificial film formed along the side surface of the first pattern;
transferring the second pattern to a mask film;
etching the active regions using the mask film as a mask in order to form a first word trench and a second word trench; and
forming the first word line and the second word line by filling the first word trench in the second word trench with a conductor.

23. The method for manufacturing a semiconductor device as claimed in claim 21, comprising:
forming a plurality of the first word lines and a plurality of the second word lines disposed in the memory cell region with an unequal pitch interval in the second direction; and
forming a plurality of the first word lines and a plurality of the second word lines formed in the word line contact region with an equal pitch interval in the second direction.

24. The method for manufacturing a semiconductor device as claimed in claim 21, comprising forming a word line contact plug on either the first word line or the second word line in the word line contact region.

25. The method for manufacturing a semiconductor device as claimed in claim 24, wherein the first word line and the second word line located in the dummy pattern region increase in width from the memory cell region toward the word line contact region, whereby short-circuiting between the word line contact plug and the adjacent first word line or second word line is avoided.

26. The method for manufacturing a semiconductor device as claimed in claim 21, wherein the interval of the dummy pattern region in the first direction is 2 to 3 times the arrangement pitch of the active regions which are adjacent in the first direction.

27. The method for manufacturing a semiconductor device as claimed in claim 21, comprising arranging the first word line and the second word line forming the word line pair with line symmetry about a centerline located therebetween and extending in the first direction.

28. The method for manufacturing a semiconductor device as claimed in claim 24, comprising arranging the word line contact plugs in a staggered manner in the second direction.

29. The method for manufacturing a semiconductor device as claimed in claim 21, wherein:
one active region comprises a bit line contact region located between the first word line and the second word line;
a bit line connected to the plurality of bit line contact regions adjacent in the second direction and extending in the second direction comprises a first bit line extending parallel to the active region and a second bit line extending over the bit line contact region while intersecting the active region; and
the bit line is formed by a snake pattern in which the first bit line and the second bit line are connected in an alternating arrangement in each active region.

30. The method for manufacturing a semiconductor device as claimed in claim 29, wherein the bit line formed by the snake pattern is such that a connection between the first bit line and the second bit line has a vertex, a capacitor is formed between vertices of two bit lines adjacent in the first direction, and the capacitor has a closest-packing arrangement.
